(19) United States
(12) Patent Application Publication
(10) Pub. No.: US 2023/0040727 A1
(43) Pub. Date: Feb. 9, 2023

(54) SEMICONDUCTOR DEVICE

(71) Applicant: Mitsubishi Electric Corporation, Tokyo (JP)

(72) Inventors: Yuki HATA, Tokyo (JP); Tsuyoshi OSAGA, Tokyo (JP); Yasuo ATA, Tokyo (JP)

(73) Assignee: Mitsubishi Electric Corporation, Tokyo (JP)

(21) Appl. No.: 17/759,134

(22) PCT Filed: May 13, 2020
(86) PCT No.: PCT/JP2020/019138

§ 371 Date: Jul. 20, 2022

(51) Int. Cl. H01L 21/768; H01L 21/52; H01L 21/67; H01L 23/492

(52) U.S. Cl. CPC H01L 21/7685; H01L 21/52; H01L 21/67288; H01L 23/4926

(57) ABSTRACT

A semiconductor device includes: a semiconductor substrate; an upper surface electrode formed on an upper surface side of the semiconductor substrate; an insulating film formed on the upper surface side of the semiconductor substrate; and a lower surface electrode formed on a lower surface side of the semiconductor substrate and having a larger area than that of the upper surface electrode, wherein the upper surface electrode and the lower surface electrode are electrodes having a compressive stress.

### FIELD

The present disclosure relates to a semiconductor device.

### BACKGROUND

A high heat radiation property is required in a semiconductor device for power applications, for example. Accordingly, the semiconductor device is generally die-bonded by using an entire lower surface of the device as an electrode and bonding the electrode to a heat radiation member or the like. Specifically, a collector electrode is provided on the entire lower surface of the device, and the collector electrode is bonded to the heat radiation member.

On the other hand, an emitter electrode and a gate electrode are mainly formed on the upper surface side of the semiconductor device. On a surface where the emitter electrode and the gate electrode are formed, an electrode region may be narrowed down to a required size, and a portion other than the electrodes is covered with a surface protective film.

This results in a difference in electrode size between an upper surface and a lower surface of the semiconductor device. Accordingly, the semiconductor device warps in an upward convex shape. In this case, there has been a problem that voids are easily accumulated under the semiconductor device at the time of die bonding so that a heat radiation property of the semiconductor device becomes insufficient. Generally, to reduce warping of the semiconductor device, the respective electrodes on the lower surface and the upper surface can be separately film-formed to change their thicknesses, and the respective electrode sizes on the upper surface side and the lower surface side can be made to approximate each other. However, this produces harmful effects such as a complication of manufacturing processes and an increase in manufacturing costs.

Patent Literature 1 discloses that a wafer can be prevented from warping by collectively forming both-surface electrodes by electroless plating.

### CITATION LIST

### Patent Literature

[Patent Literature 1] JP 2013-194291 A

### SUMMARY

### Technical Problem

However, in a method described in Patent Literature 1, warping of a semiconductor device cannot be sufficiently improved. In the collective formation of the both-surface electrodes by electroless plating, the respective thicknesses of an upper surface electrode and a lower surface electrode are equal to each other. Thus, if the upper surface electrode and the lower surface electrode differ in size, a stress difference occurs in proportion to the difference in size. Accordingly, the semiconductor device warps. For example, if respective tensile stresses as forces to make a material contacting the upper surface electrode and the lower surface electrode contract are exerted on the electrodes, the electrode having the larger area out of the upper surface electrode and the lower surface electrode exerts the larger tensile stress. If the area of the lower surface electrode is larger than the area of the upper surface electrode, the semiconductor device warps to be convex toward its upper surface side.

Further, in recent years, the device size has been made larger than 1 cm² and the device thickness has been set to 100 μm or less to enable large current energization. Thus, the semiconductor device easily warps.

The present disclosure has been made to solve the above-described problem, and is directed to providing a semiconductor device having an improved warping shape.

### Solution to Problem

A semiconductor device according to the present disclosure includes: a semiconductor substrate; an upper surface electrode formed on an upper surface side of the semiconductor substrate; an insulating film formed on the upper surface side of the semiconductor substrate; and a lower surface electrode formed on a lower surface side of the semiconductor substrate and having a larger area than that of the upper surface electrode, wherein the upper surface electrode and the lower surface electrode are electrodes having a compressive stress.

Another semiconductor device according to the present disclosure includes: a semiconductor substrate; an upper surface conductive layer formed on an upper surface side of the semiconductor substrate; a tensile stress film formed on the upper surface side of the upper surface conductive layer; an upper surface electrode formed on an upper surface side of the tensile stress film; an insulating film formed adjacent to the upper surface electrode on the upper surface side of the semiconductor substrate; and a lower surface electrode formed on a lower surface side of the semiconductor substrate and having a larger area than that of the upper surface electrode, wherein the tensile stress film has a larger tensile stress than that of the upper surface conductive layer.

Other features of the present disclosure are clarified below.

### Advantageous Effects of Invention

In the present disclosure, by adjusting the stress on the upper surface side of the semiconductor substrate, the warped shape of the semiconductor device can be improved.

### BRIEF DESCRIPTION OF THE DRAWINGS

FIG. 1 is a cross-sectional view of a termination of a semiconductor device according to a first embodiment.

FIG. 2 is a diagram illustrating a relationship between a phosphorus content and an internal stress of a nickel-phosphorous alloy plating.

FIG. 3 is a plan view, a right side view, and a front view of the semiconductor device.

FIG. 4 is a cross-sectional view of a termination of a semiconductor device according to a second embodiment.

FIG. 5 is a cross-sectional view of a termination of a semiconductor device according to a third embodiment.

### DESCRIPTION OF EMBODIMENTS

A semiconductor device according to the embodiments will be described with reference to the drawings. The same components will be denoted by the same symbols, and the repeated description thereof may be omitted.

### First Embodiment

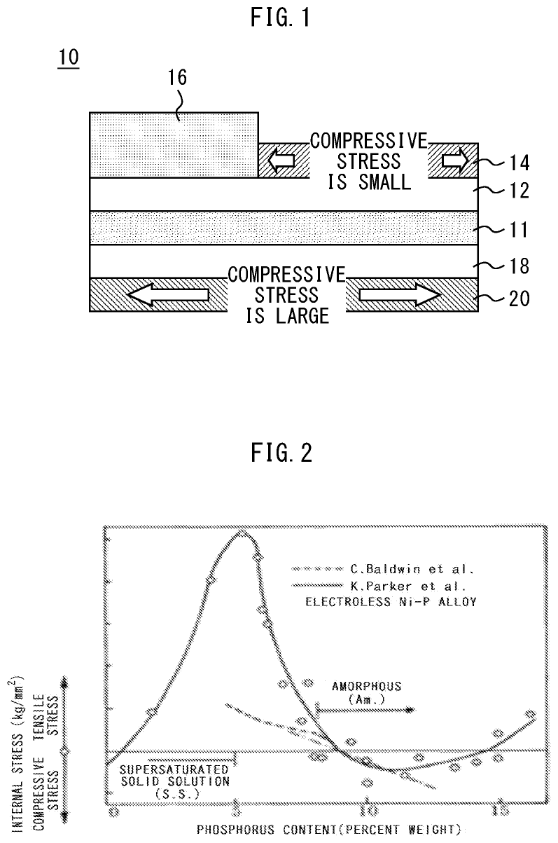

FIG. 1 is a cross-sectional view of a termination of a semiconductor device 10 according to a first embodiment. The semiconductor device 10 includes a semiconductor substrate 11. According to one example, the semiconductor substrate 11 is Si or SiC. An upper surface conductive layer 12 is provided on the upper surface side of the semiconductor substrate 11. A lower surface conductive layer 18 is provided on the lower surface side of the semiconductor substrate 11. An example of a material for the upper surface conductive layer 12 and the lower surface conductive layer 18 is AlSi, Al, or an Al alloy.

An upper surface electrode 14 and an insulating film 16 are formed on the upper surface side of the semiconductor substrate 11. The upper surface electrode 14 is NiP having a phosphorus (P) content of 9 to 14%. The insulating film 16 functions as a surface protective film. In this example, the upper surface electrode 14 and the insulating film 16 contact an upper surface of the upper surface conductive layer 12.

A lower surface electrode 20 is formed on the lower surface side of the semiconductor substrate 11. The lower surface electrode 20 is NiP having a phosphorus content of 9 to 14%. According to one example, the lower surface electrode 20 and the upper surface electrode 14 can be collectively formed by electroless NiP plating. In this case, the respective thicknesses of the lower surface electrode 20 and the upper surface electrode 14 are equal to each other. In this example, the lower surface electrode 20 contacts a lower surface of the lower surface conductive layer 18.

The area of the lower surface electrode 20 is larger than the area of the upper surface electrode 14. According to one example, the upper surface electrode 14 exists on a part of the upper side of the semiconductor substrate 11, and the lower surface electrode 20 exists on the entire lower side of the semiconductor substrate 11. A plurality of upper surface electrodes 14 can be provided, and one of the electrodes and the other one of the electrodes can be respectively set as an emitter electrode and a gate electrode. The upper surface electrode 14 exists on the upper surface side of the semiconductor device 10, and the insulating film 16 is formed in a portion where the upper surface electrode 14 does not exist.

The lower surface electrode 20 can be set as a collector electrode provided on the entire lower surface side of the semiconductor substrate 11. Formation of the collector electrode on the entire lower surface of the semiconductor device 10 contributes to enhancement of a heat radiation property of the semiconductor device 10.

According to one example, a length from an upper surface of the upper surface electrode 14 to a lower surface of the lower surface electrode 20 is 100 um or less. Therefore, the semiconductor device 10 is relatively thin. According to another example, another length can be adopted.

FIG. 2 is a diagram illustrating a relationship between a phosphorus content and an internal stress of an electroless nickel-phosphorous alloy plating. FIG. 2 has been taken from J. J. Grundwaid, H. Rhodenizer, L. Slominski, Plating 58, 1004 (1971). According to FIG. 2, if a phosphorus content is 9 to 14% in NiP, a compressive stress occurs in an NiP alloy. As described above, the upper surface electrode 14 and the lower surface electrode 20 are each NiP having a phosphorus content of 9 to 14%. Accordingly, a compressive stress to stretch a material contacting the upper surface electrode 14 and the lower surface electrode 20 occurs in the electrodes. Since the area of the lower surface electrode 20 is larger than the area of the upper surface electrode 14, a relatively small compressive stress occurs in the upper surface electrode 14, and a relatively large compressive stress occurs in the lower surface electrode 20.

As a result, the semiconductor device 10 warps in a downward convex shape. In other words, the semiconductor substrate 11 is convex toward the lower surface electrode 20 side. In the semiconductor device 10 that warps in a downward convex shape, voids can be more difficult to generate by die-bonding the lower surface electrode 20 than those in a semiconductor device that warps in an upward convex shape. A compressive stress may be produced in the upper surface electrode 14 and the lower surface electrode 20 using a material other than “NiP having a phosphorus content of 9 to 14%” for the electrodes.

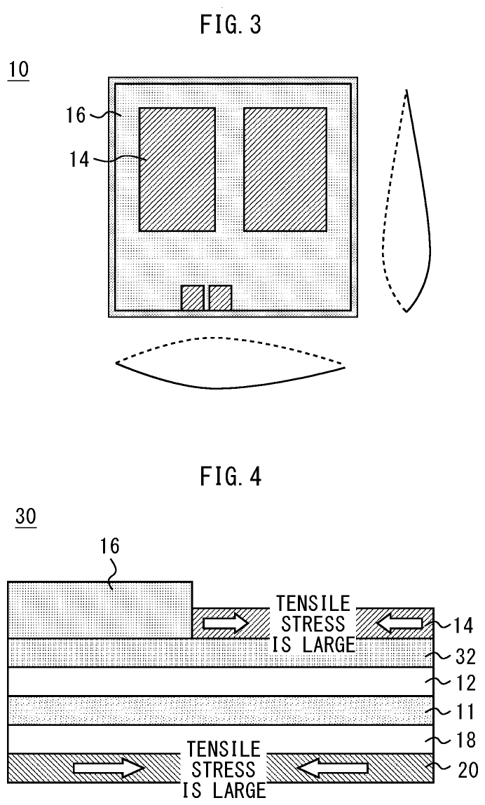

FIG. 3 is a plan view, a right side view, and a front view of the semiconductor device 10. The plan view, the right side view, and the front view are respectively located at the center of, on the right side of, and in a lower part of FIG. 3. A solid line in each of the right side view and the front view indicates a shape of the semiconductor device 10. Since the semiconductor device 10 warps in a downward convex shape, voids are not easily generated in a bonding material when a lower surface of the semiconductor device 10 is die-bonded.

A broken line in each of the right side view and the front view in FIG. 3 indicates a shape of the semiconductor device that warps in an upward convex shape. In a thin semiconductor device having a thickness of 100 μm or less, for example, the semiconductor device easily warps. Thus, an amount of warping is larger when the semiconductor device warps in an upward convex shape. Since the semiconductor device indicated by the broken line warps in an upward convex shape, voids are easily generated in a bonding material when a lower surface of the semiconductor device is die-bonded.

The semiconductor device 10 according to the first embodiment can be provided as a power semiconductor device such as an IGBT, a MOSFET, or a diode, for example. A structure different from a cross-sectional structure illustrated in FIG. 1 can also be adopted in a range in which the above-described characteristic is not lost. A difference from the first embodiment will be mainly described for respective semiconductor devices according to the following embodiments. A variation, a modification, or an alternative described in the first embodiment can be applied to the respective semiconductor devices according to the following embodiments.

### Second Embodiment

FIG. 4 is a cross-sectional view of a termination of a semiconductor device 30 according to a second embodiment. A tensile stress film 32 is formed on the upper surface side of an upper surface conductive layer 12. The tensile stress film 32 has a larger tensile stress than that of the upper surface conductive layer 12. For example, the upper surface conductive layer 12 is AlSi, and the tensile stress film 32 is Ti. A lower surface electrode 20 having a larger area than that of an upper surface electrode 14 is provided on the lower surface side of a semiconductor substrate 11, like in the first embodiment.

The upper surface electrode 14 and an insulating film 16 are formed on the upper surface side of the tensile stress film 32. In this example, the tensile stress film 32 contacts a lower surface of the upper surface electrode 14 and a lower surface of the insulating film 16. The insulating film 16 can be formed adjacent to the upper surface electrode 14 on the upper surface side of the semiconductor substrate 11.

As described above, a tensile stress of the tensile stress film 32 is larger than a tensile stress of the upper surface conductive layer 12. Thus, a tensile stress to be exerted on the upper surface electrode 14 can be made larger than that when the upper surface conductive layer 12 contacts the upper surface electrode 14. The tensile stress film 32 is thus provided, to strengthen a tensile stress on the upper surface side of the semiconductor device 30. This makes it possible to reduce an amount of warping of the semiconductor device that warps in an upward convex shape, prevent warping, and cause the semiconductor device to warp in a downward convex shape.

If Ti is adopted as the tensile stress film 32 and AlSi is adopted as the upper surface conductive layer 12, the semiconductor device can be prevented from warping to be convex toward its upper surface side without reducing an energization capability since a contact resistance is suppressed because Ti has a smaller work function as that of AlSi. This effect can also be obtained by adopting another material.

### Third Embodiment

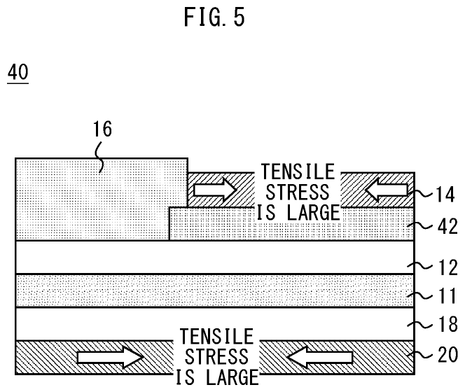

FIG. 5 is a cross-sectional view of a termination of a semiconductor device 40 according to a third embodiment. The semiconductor device 40 according to the third embodiment differs from the semiconductor device 30 according to the second embodiment in an arrangement position of a tensile stress film 42. The tensile stress film 42 contacts a lower surface of an upper surface electrode 14 and a side surface of an insulating film 16. In another example, the tensile stress film 42 contacts the lower surface of the upper surface electrode 14 and does not contact a lower surface of the insulating film 16.

The tensile stress film 42 according to the third embodiment is not provided on an entire upper surface of the upper surface conductive layer 12 but is mainly formed only under the upper surface electrode 14. This makes it possible to reduce costs by adding the tensile stress film 42 while strengthening a tensile stress on the upper surface side of the semiconductor device 40 by the tensile stress film 42.

### REFERENCE SIGNS LIST

11 semiconductor substrate; 12 upper surface conductive layer; 14 upper surface electrode; 16 insulating film; 18 lower surface conductive layer; 20 lower surface electrode; 32,42 tensile stress film

1. A semiconductor device comprising:
a semiconductor substrate;
an upper surface electrode formed on an upper surface side of the semiconductor substrate;
an insulating film formed on the upper surface side of the semiconductor substrate; and
a lower surface electrode formed on a lower surface side of the semiconductor substrate and having a larger area than that of the upper surface electrode,
wherein the upper surface electrode and the lower surface electrode are electrodes having a compressive stress.

2. The semiconductor device according to claim 1, wherein a phosphorus content is 9 to 14% in the upper surface electrode and the lower surface electrode.

3. A semiconductor device comprising:
a semiconductor substrate;
an upper surface conductive layer formed on an upper surface side of the semiconductor substrate;
a tensile stress film formed on the upper surface side of the upper surface conductive layer;
an upper surface electrode formed on an upper surface side of the tensile stress film;
an insulating film formed adjacent to the upper surface electrode on the upper surface side of the semiconductor substrate; and
a lower surface electrode formed on a lower surface side of the semiconductor substrate and having a larger area than that of the upper surface electrode,
wherein the tensile stress film has a larger tensile stress than that of the upper surface conductive layer.

4. The semiconductor device according to claim 3, wherein the tensile stress film contacts a lower surface of the upper surface electrode and a lower surface of the insulating film.

5. The semiconductor device according to claim 3, wherein the tensile stress film contacts a lower surface of the upper surface electrode and a side surface of the insulating film.

6. The semiconductor device according to claim 3, wherein the tensile stress film contacts a lower surface of the upper surface electrode and does not contact a lower surface of the insulating film.

7. The semiconductor device according to claim 3, wherein the upper surface electrode and the lower surface electrode are NiP, the tensile stress film is Ti, and the upper surface conductive layer is AlSi.

8. The semiconductor device according to claim 1, wherein the semiconductor substrate is Si.

9. The semiconductor device according to claim 1, wherein a length from an upper surface of the upper surface electrode to a lower surface of the lower surface electrode is 100 μm or less.

10. The semiconductor device according to claim 1, wherein the semiconductor substrate is convex toward the lower surface electrode side.

11. The semiconductor device according to claim 4, wherein the upper surface electrode and the lower surface electrode are NiP, the tensile stress film is Ti, and the upper surface conductive layer is AlSi.

12. The semiconductor device according to claim 5, wherein the upper surface electrode and the lower surface electrode are NiP, the tensile stress film is Ti, and the upper surface conductive layer is AlSi.

13. The semiconductor device according to claim 6, wherein the upper surface electrode and the lower surface electrode are NiP, the tensile stress film is Ti, and the upper surface conductive layer is AlSi.

14. The semiconductor device according to claim 3, wherein the semiconductor substrate is Si.

15. The semiconductor device according to claim 3, wherein a length from an upper surface of the upper surface electrode to a lower surface of the lower surface electrode is 100 μm or less.

16. The semiconductor device according to claim 3, wherein the semiconductor substrate is convex toward the lower surface electrode side.
